(19) United States
(12) Patent Application Publication
(10) Pub. No.: US 2026/0068756 A1
(43) Pub. Date: Mar. 5, 2026

(54) MEMORY DEVICE AND METHOD OF MANUFACTURING THE SAME

(71) Applicant: SK hynix Inc., Gyeonggi-do (KR)

(72) Inventor: Heon Yong CHANG, Gyeonggi-do (KR)

(21) Appl. No.: 19/012,907

(22) Filed: Jan. 8, 2025

(30) Foreign Application Priority Data
Sep. 5, 2024 (KR) 10-2024-0120487

(51) Int. Cl. H01L 25/07; H10B 80/00

(52) U.S. Cl. CPC H01L 25/074; H10B 80/00

(57) ABSTRACT

A memory device may include a first semiconductor chip including a first bonding insulating layer, a second semiconductor chip bonded to the first semiconductor chip and including a second bonding insulating layer, a through contact including a first portion vertically penetrating the first bonding insulating layer and the second bonding insulating layer, and a second portion located below the first portion and having a width greater than a width of the first portion, and a spacer disposed on a side surface of the first portion of the through contact.

### CROSS-REFERENCE TO RELATED APPLICATION

The present application claims priority under 35 U.S.C. 119(a) to Korean patent application number 10-2024-0120487 filed on Sep. 5, 2024, which is incorporated herein by reference in its entirety.

### TECHNICAL FIELD

The embodiments of the present disclosure relate generally to semiconductor technology and, more particularly, to a memory device and method of manufacturing the same.

### BACKGROUND

Memory devices are crucial components because they have evolved significantly, becoming smaller, more efficient, and cheaper to produce. This evolution has been a major driving force in technological advancements, from smartphones to laptops, enhancing both performance and functionality. However, further improvements in the integration of a memory device requires reducing a line width of the wiring included in the memory device, which increases the difficulty of manufacturing the memory device.

For achieving high integration of the memory device, a process bonding two wafers together has been proposed with one wafer including memory cells and the other wafer including peripheral circuits for controlling the memory cells. The wafers are manufactured separately and then the two wafers are bonded. In the process of bonding the wafers, it is important to optimize the process conditions so that the two wafers are evenly attached without any gaps or lifting occurring.

### SUMMARY

An embodiment of the present disclosure includes providing a memory device capable of preventing the deterioration of device characteristics due to process defects, and a method of manufacturing the same.

According to an embodiment of the present disclosure a memory device may include a first semiconductor chip including a first bonding insulating layer, a second semiconductor chip bonded to the first semiconductor chip and including a second bonding insulating layer, a through contact including a first portion vertically penetrating the first bonding insulating layer and the second bonding insulating layer, and a second portion located below the first portion and having a width greater than a width of the first portion, and a spacer disposed on a side surface of the first portion of the through contact.

According to an embodiment of the present disclosure a memory device may include a bonding insulating layer including a first bonding insulating layer, and a second bonding insulating layer disposed on the first bonding insulating layer and bonded to the first bonding insulating layer, a through contact including a first portion vertically penetrating the bonding insulating layer, and a second portion located below the first portion and having a width greater than a width of the first portion, and a spacer disposed between the first portion of the through contact and the bonding insulating layer.

According to an embodiment of the present disclosure a method of manufacturing a memory device may include forming a bonding insulating layer comprising a first bonding insulating layer, and a second bonding insulating layer bonded on the first bonding insulating layer; forming a through contact including first and second portions, the first portion vertically penetrating the bonding insulating layer, and the second portion disposed below the first portion, the second portion having a width greater than a width of the first portion; and forming a spacer disposed between the first portion of the through contact and the bonding insulating layer.

According to embodiments of the present disclosure, it is possible to prevent deterioration of device characteristics of a memory device caused by process defects.

### BRIEF DESCRIPTION OF THE DRAWINGS

FIG. 1 illustrates a cross-sectional structure of a memory device according to embodiments of the present disclosure.

FIG. 2 is an enlarged view of part 10 of FIG. 1.

FIGS. 3 to 5 illustrate other embodiments of part 10 of FIG. 1.

FIGS. 6 to 16 illustrate methods for forming a memory device according to embodiments of the present disclosure.

FIGS. 17 to 25 illustrate other methods for forming a memory device according to embodiments of the present disclosure.

### DETAILED DESCRIPTION

Hereinafter, various embodiments of the present disclosure will be described in detail with reference to accompanying drawings.

In the attached drawings, two directions parallel to an top surface of the substrate are defined as a first direction FD and a second direction SD, respectively, and a direction protruding vertically from the top surface of the substrate is defined as a third direction VD. The first direction FD and the second direction SD may be substantially perpendicular to each other. The third direction VD may be a direction perpendicular to the plane defined by the first direction FD and the second direction SD. In the following specification, ‘vertical’ or ‘vertical direction’ will be used to have substantially the same meaning as the third direction VD. The direction indicated by an arrow in the drawings and its opposite direction may indicate the same direction.

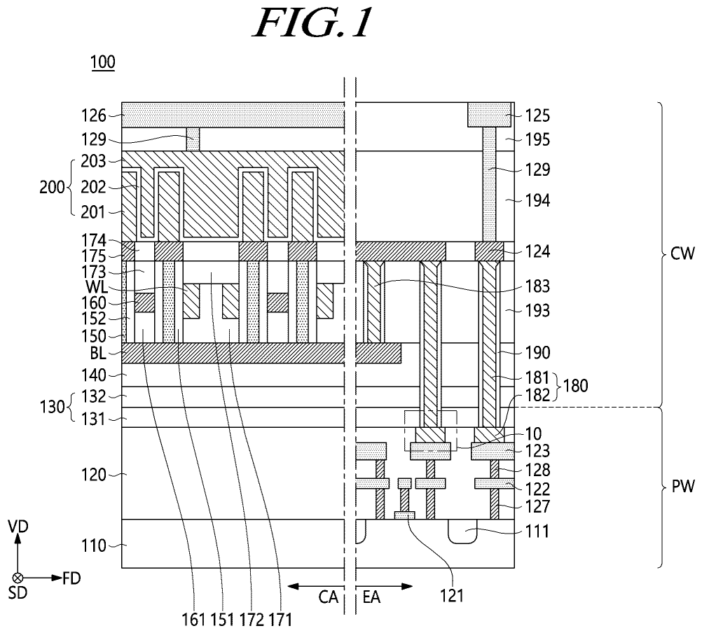

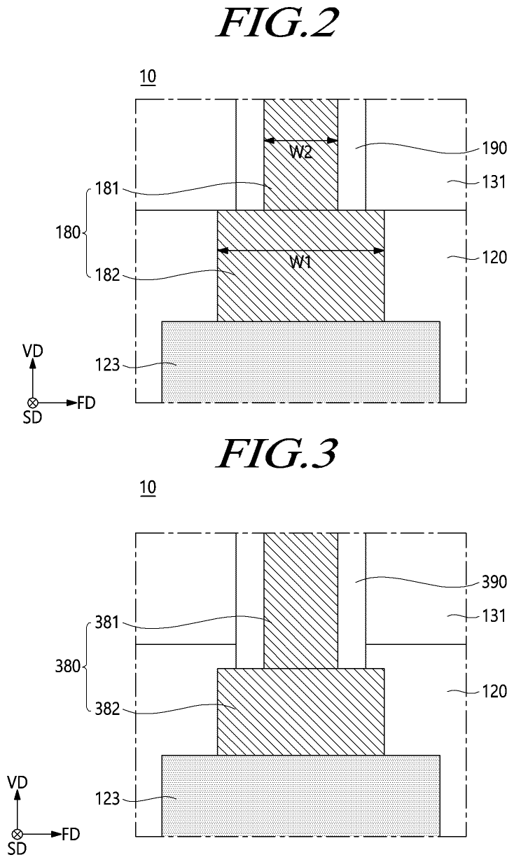

FIG. 1 illustrates a cross-sectional structure of a memory device according to embodiments of the present disclosure. FIG. 2 is an enlarged view of part 10 of FIG. 1.

Referring to FIG. 1, a memory device 100 according to embodiments of the present disclosure may include a cell area CA and an extension area EA which are adjacent to each other. The cell area CA may be an area where memory cells are disposed. The extension area EA may be located at an outer periphery of the cell area CA. In an embodiment, the extension area EA may be located at an outer periphery of the cell area CA in a first direction FD. The extension area EA may be an area where a contact for connecting a memory cell and a peripheral circuit is disposed. In an embodiment, there may be disposed a contact for connecting a bit line BL to a peripheral circuit in the extension area EA located outside the cell area CA in the first direction FD.

The memory device 100 according to embodiments of the present disclosure may include a substrate 110, a device isolation layer 111, a first insulating layer 120, a plurality of wirings 121, 122, 123, 124, 125 and 126, a plurality of contacts 127, 128 and 129, a bonding insulating layer 130, a second insulating layer 140, a bit line BL, an active layer 150, a first gate insulating layer 151, a second gate insulating layer 152, a back gate electrode 160, a gate capping layer 161, a first insulating pattern 171, a second insulating pattern 172, a third insulating pattern 173, a fourth insulating pattern 174, a word line WL, a contact plug 175, a through contact 180, a spacer 190, a third insulating layer 193, a fourth insulating layer 194, a fifth insulating layer 195, and a capacitor 200. The bonding insulating layer 130 may include a first bonding insulating layer 131 and a second bonding insulating layer 132. The through contact 180 may include a first portion 181 and a second portion 182. The capacitor 200 may include a lower electrode 201, a dielectric layer 202, and an upper electrode 203.

The substrate 110 may include a semiconductor substrate such as a silicon wafer or a silicon-on-insulator (SOI) wafer. The substrate 110 may include an III-V group semiconductor substrate, for example, a compound semiconductor substrate such as GaAs. The substrate 110 may include single crystal silicon, polysilicon, amorphous silicon, single crystal silicon germanium, polycrystalline silicon germanium, carbon-doped silicon, or a combination thereof.

In the extension area EA, at least one device isolation layer 111 may be disposed within the substrate 110. The device isolation layer 111 may be formed using a trench device isolation technology such as shallow trench isolation (STI). The device isolation layer 111 may include silicon oxide, silicon nitride, silicon oxynitride, low-K dielectrics, high-K dielectrics, or a combination thereof.

A first wiring 121, a first contact 127, a second wiring 122, a second contact 128, and a third wiring 123 may be sequentially disposed on the substrate 110. The first insulating layer 120 may be disposed to cover the first wiring 121, the first contact 127, the second wiring 122, the second contact 128, and the third wiring 123. The first wiring 121, the second wiring 122, and the first contact 127 may form one transistor included in a peripheral circuit. In an embodiment, a voltage for operating a bit line BL may be transmitted through the first contact 127 and the second wiring 122.

The first insulating layer 120 may include silicon oxide, silicon nitride, silicon oxynitride, a high-k dielectric, or a combination thereof. The first wiring 121, the first contact 127, the second wiring 122, the second contact 128, and the third wiring 123 may include a conductive material such as a metal, a metal oxide, a metal nitride, a metal silicide, polysilicon, conductive carbon, or a combination thereof.

The first bonding insulating layer 131 may be disposed on the first insulating layer 120. The second bonding insulating layer 132 may be disposed on the upper surface of the first bonding insulating layer 131. The lower surface of the second bonding insulating layer 132 may contact the upper surface of the first bonding insulating layer 131. The lower surface of the second bonding insulating layer 132 may be bonded to the upper surface of the first bonding insulating layer 131. In an embodiment, the memory device 100 may include a structure in which a first semiconductor chip PW including a first bonding insulating layer 131 and a second semiconductor chip CW including a second bonding insulating layer 132 are bonded. A memory cell may be disposed in the second semiconductor chip CW. The first semiconductor chip PW may be referred to as a circuit chip. The second semiconductor chip CW may be referred to as a memory chip.

The first bonding insulating layer 131 and the second bonding insulating layer 132 may include silicon oxide, silicon nitride, silicon oxynitride, silicon carbonitride, a high-k dielectric, or a combination thereof. In an embodiment, the first bonding insulating layer 131 and the second bonding insulating layer 132 may include silicon carbonitride.

The second insulating layer 140 may be disposed on the second bonding insulating layer 132. The bit line BL may be disposed on the second insulating layer 140. The bit line BL may extend along the first direction FD. The bit line BL may extend from the cell area CA to the extension area EA along the first direction FD. The second insulating layer 140 may include silicon oxide, silicon nitride, silicon oxynitride, silicon carbonitride, a high-k dielectric, or a combination thereof. The bit line BL may include a conductive material such as a metal, a metal nitride, a metal silicide, polysilicon, conductive carbon, or a combination thereof.

A memory cell may be disposed on the bit line BL in the cell area CA. In an embodiment, the memory cell may include one transistor and one capacitor. Hereinafter, it will be described that a memory cell includes one transistor and one capacitor.

The active layer 150 may contact the bit line BL and may extend in the vertical direction. The active layer 150 may include a channel region formed in an area overlapping with the word line WL or the back gate electrode 160 in the first direction FD. The active layer 150 may include a source or drain region formed around the channel region. The active layer 150 may include polysilicon or single crystal silicon.

The first gate insulating layer 151 and a second gate insulating layer 152 may be disposed on the side surface of the active layer 150. The first gate insulating layer 151 may be disposed between the active layer 150 and the word line WL in the first direction FD. The first gate insulating layer 151 may extend in the vertical direction. The second gate insulating layer 152 may be disposed between the active layer 150 and the back gate electrode 160 in the first direction FD. The second gate insulating layer 152 may extend in the vertical direction. The first gate insulating layer 151 and the second gate insulating layer 152 may include silicon oxide, silicon nitride, silicon oxynitride, silicon carbonitride, high-k dielectric, or a combination thereof.

The word line WL, the first insulating pattern 171, and the second insulating pattern 172 may be disposed between the opposing first gate insulating layers 151. The vertical length of the word line WL may be less than the vertical length of the active layer 150. The first insulating pattern 171 may be located between the opposing word lines WL. The first insulating pattern 171 may cover one side and the lower surface of the word line WL. The second insulating pattern 172 may cover the upper surface of the first insulating pattern 171 and the word line WL.

The back gate electrode 160, the gate capping layer 161, and the third insulating pattern 173 may be located between the opposing second gate insulating layers 152. The vertical length of the back gate electrode 160 may be less than the vertical length of the active layer 150. The gate capping layer 161 may be positioned between the back gate electrode 160 and the bit line BL. The third insulating pattern 173 may be positioned on the back gate electrode 160. The gate capping layer 161, the back gate electrode 160, and the third insulating pattern 173 may overlap with each other in the vertical direction

The word line WL and the back gate electrode 160 may include a conductive material such as a metal, a metal nitride, a metal silicide, polysilicon, a conductive carbon, or a combination thereof. The first insulating pattern 171, the second insulating pattern 172, the third insulating pattern 173, the fourth insulating pattern 174, and the gate capping layer 161 may include silicon oxide, silicon nitride, silicon oxynitride, silicon carbon nitride, a high-k dielectric, or a combination thereof.

The fourth insulating pattern 174 and the contact plug 175 may be disposed on the active layer 150, the first and second gate insulating layers 151 and 152, the second insulating pattern 172, and the third insulating pattern 173. The contact plug 175 may correspond to one active layer 150. The contact plug 175 may contact the upper surface of the corresponding active layer 150. The fourth insulating pattern 174 may be disposed between the contact plugs 175. The contact plug 175 may include a conductive material such as a metal, a metal nitride, a metal silicide, polysilicon, a conductive carbon, or a combination thereof. The fourth insulating pattern 174 may include silicon oxide, silicon nitride, silicon oxynitride, silicon carbon nitride, a high-k dielectric, or a combination thereof.

A bit line connection contact 183 and the spacer 190 may be disposed on the bit line BL in the extension area EA. The spacer 190 may be disposed on the side surface of the bit line connection contact 183. The spacer 190 may surround the side surface of the bit line connection contact 183. A fourth wiring 124 and a fourth insulating pattern 124 may be disposed on the bit line connection contact 183 and the spacer 190.

The through contact 180 may be disposed on a third wiring 123. The through contact 180 may extend in a vertical direction. The through contact 180 may extend into the first insulating layer 120 by penetrating the third insulating layer 193, the second insulating layer 140, the second bonding insulating layer 132 and the first bonding insulating layer 131 in the vertical direction. The lower surface of the through contact 180 may contact the third wiring 123. The upper surface of the through contact 180 may contact the fourth wiring 124. The bit line BL may be electrically connected to the third wiring 123 through the bit line connection contact 183, the fourth wiring 124, and the through contact 180. The through contact 180 may be disposed outside an area where the bit line BL is disposed in the first direction FD.

The spacer 190 may be disposed on a portion of the side surface of the through contact 180. The spacer 190 may surround a portion of the side surface of the through contact 180.

The bit line connection contact 183, the fourth wiring 124, and the through contact 180 may include a conductive material such as a metal, a metal oxide, a metal nitride, a metal silicide, polysilicon, conductive carbon, or a combination thereof. The spacer 190 may include silicon oxide, silicon nitride, silicon oxynitride, a high-k dielectric, or a combination thereof.

The capacitor 200 may be disposed on the fourth insulating pattern 174 and the contact plug 175 in the cell area CA. The lower electrode 201 of the capacitor 200 may correspond to one contact plug 175. The lower electrode 201 may contact the upper surface of the contact plug 175. The dielectric layer 202 may be disposed to cover the side surface and the upper surface of the lower electrode 201 and the upper surface of the fourth insulating pattern 174. In an embodiment, the dielectric layer 202 may conformally cover the side surface and the upper surface of the lower electrode 201. The upper electrode 203 may be disposed on the dielectric layer 202. The lower electrode 201 and the upper electrode 203 may include a conductive material such as a metal, a metal oxide, a metal nitride, a metal silicide, polysilicon, a conductive carbon, or a combination thereof. The dielectric layer 202 may include a high-k material, silicon oxide, silicon nitride, or a combination thereof.

The third contact 129 and the fifth insulating layer 195 may be disposed on the upper electrode 203. A sixth wiring 126 may be disposed on a third contact 129.

The fourth insulating layer 194 and the third contact 129 may be disposed on the fourth wiring 124 and the fourth insulating pattern 174 in the extension area EA. The third contact 129 may penetrate the fourth insulating layer 194 and contact an upper surface of at least one fourth wiring 124. The fifth insulating layer 195 may be disposed on the fourth insulating layer 194. A fifth wiring 125 may be disposed within the fifth insulating layer 195.

Referring to FIG. 1 and FIG. 2, the through contact 180 may include a first portion 181 and a second portion 182. The second portion 182 may be disposed on the third wiring 123. The lower surface of the second portion 182 may contact the upper surface of the third wiring 123. The upper surface of the second portion 182 may contact the lower surface of the spacer 190. In an embodiment, the upper surface of the second portion 182 may contact the lower surface of the first bonding insulating layer 131.

The first portion 181 may be disposed on the second portion 182. The first portion 181 may extend in a vertical direction and penetrate the first bonding insulating layer 131 and the second bonding insulating layer 132. The first portion 181 may also penetrate the third and second insulating layers 193, and 140. The first portion 181 may be continuous with the second portion 182. In an embodiment, the width W1 of the second portion 182 in the first direction FD may be greater than the width W2 of the first portion 181 of the through contact 180 in the first direction FD. The second portion 182 of the through contact 180 may not extend in the bonding insulating layer 130 and may be disposed between the third wiring 123 and the first bonding insulating layer 131.

The spacer 190 may be disposed on a side surface of the first portion 181 of the through contact 180. The spacer 190 may surround the side surface of the first portion 181 of the through contact. In the embodiment of FIG. 2, the lower surface of the spacer 190 may be substantially at the same plane as the lower surface of the first bonding insulating layer 131.

FIGS. 3 to 5 illustrate other embodiments of part 10 of FIG. 1.

Referring to FIG. 3, a variation of the through contact is illustrated. Specifically, through contact 380 may include a first portion 381 and a second portion 382 with the lower surface of the second portion 382 contacting the upper surface of the third wiring 123, and the upper surface of the second portion 382 contacting the lower surface of spacer 390. In the embodiment of FIG. 3, the upper surface of the second portion 382 of the through contact 380 may be spaced apart from the lower surface of the first bonding insulating layer 131.

The first portion 381 of the through contact 380 may be disposed on the second portion 382 of the through contact 380. The first portion 381 of the through contact 380 may be continuous with the second portion 382 of the through contact 380. In an embodiment, the first portion 381 of the through contact 380 may protrude downward from the lower surface of the first bonding insulating layer 131 in the vertical direction. For example, the lower surface of the first portion 381 of the through contact 380 may be located at a lower level in the vertical direction than the lower surface of the first bonding insulating layer 131.

The spacer 390 may be disposed on the side surface of the first portion 381 of the through contact 380. In an embodiment, the spacer 390 may protrude downward from a lower surface of the first bonding insulating layer 131 in the vertical direction. For example, the lower surface of the spacer 390 may be located at a lower level in the vertical direction than the lower surface of the first bonding insulating layer 131.

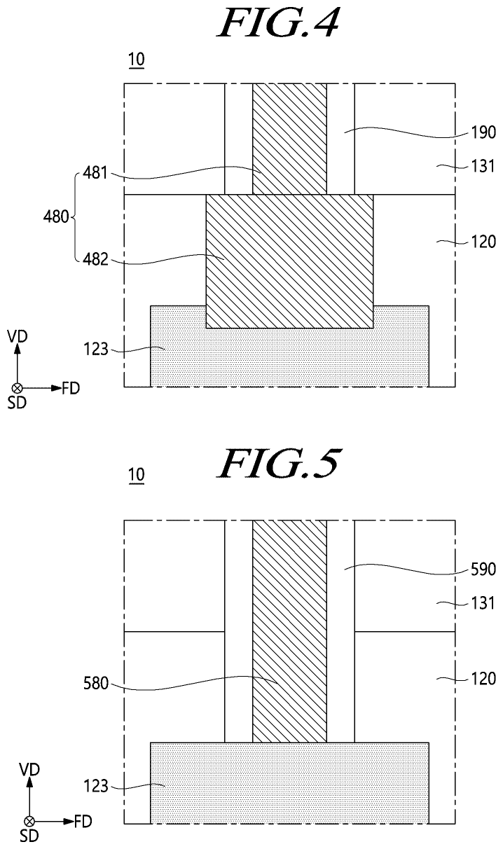

Referring to FIG. 4, the through contact 480 may include a first portion 481 and a second portion 482. In the embodiment of FIG. 4, the second portion 482 of the through contact 480 may extend into the interior of the third wiring 123 in the vertical direction. A portion of the side surface and the lower surface of the second portion 482 of the through contact 480 may contact the third wiring 123.

The first portion 481 of the through contact 480 may be disposed on the second portion 482 of the through contact 480. The first portion and second portions 481, 482 of the through contact 480 may be continuous to the second portion 482. The first portion 481 of the through contact 480 may be substantially identical to a first portion 181 of the through contact 180 described with reference to FIG. 2.

Referring to FIG. 5, another variation of the through contact is provided and denoted with numeral 580. Through contact 580 may penetrate the second bonding insulating layer 132 and the first bonding insulating layer 131 in the vertical direction, and may contact the upper surface of the third wiring 123. In the embodiment of FIG. 5, the width of the through contact 580 may be uniform.

The spacer 590 may be disposed on the side surface of the through contact 580 and may surround the side surface of the through contact 580. The spacer 590 may protrude downward from a lower surface of the first bonding insulating layer 131 in the vertical direction. In the embodiment of FIG. 5, the lower surface of the spacer 590 may contact the upper surface of the third wiring 123.

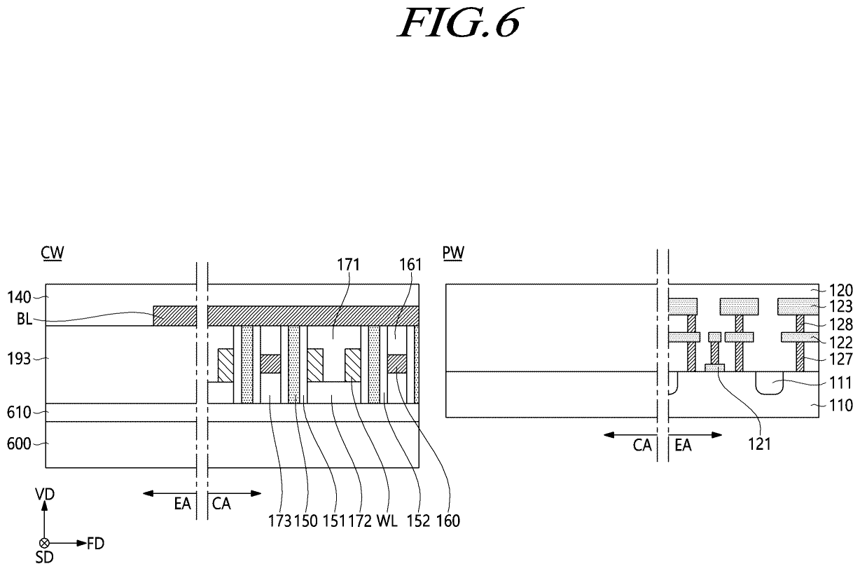

FIGS. 6 to 16 illustrate methods for forming a memory device according to embodiments of the present disclosure.

Referring to FIG. 6, first and second semiconductor chips CW may be prepared. The second semiconductor chip CW may include a first substrate 600, a sixth insulating layer 610 formed on the first substrate 600, third insulating layer 193 formed on the sixth insulating layer 610, active layer 150, first gate insulating layer 151, second gate insulating layer 152, word line WL, back gate electrode 160, gate capping layer 161, a first insulating pattern 171, a second insulating pattern 172, and a third insulating pattern 173, and a bit line BL and a second insulating layer 140 formed on the third insulating layer 193.

The first semiconductor chip PW may include substrate 110, device isolation layer 111 formed within the substrate 110, first wiring 121 formed on the substrate 110, first contact 127 formed on the substrate 110, second wiring 122 formed on first contact 127, second contact 128 formed on second wiring 122, a third wiring 123 formed on second contact, and a first insulating layer 120. The device isolation layer 111, the first, second and third wirings 121, 122, and 123, the first and second contacts 127 and 128 may be formed inside the first insulating layer 120.

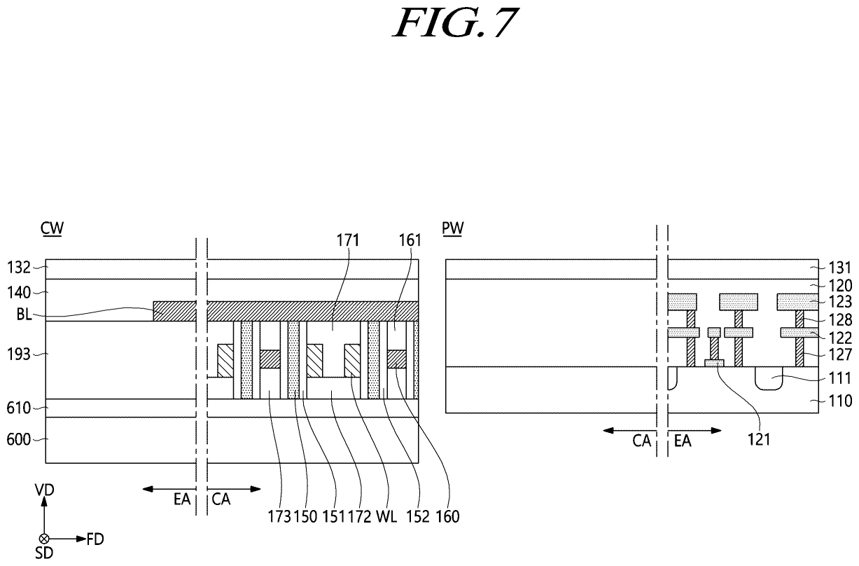

Referring to FIG. 7, a second bonding insulating layer 132 may be formed on the second insulating layer 140 of the second semiconductor chip CW. A first bonding insulating layer 131 may be formed on the first insulating layer 120 of the first semiconductor chip PW. The first bonding insulating layer 131 may include the same material as the material forming the second bonding insulating layer 132. In an embodiment, the first bonding insulating layer 131 and the second bonding insulating layer 132 may include silicon carbon nitride.

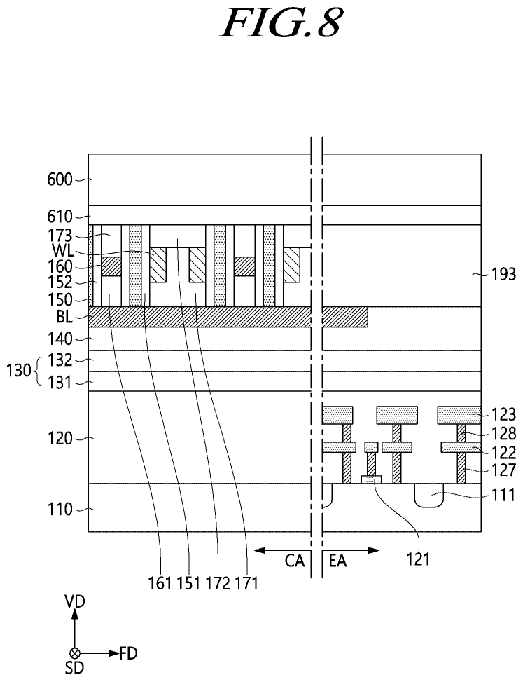

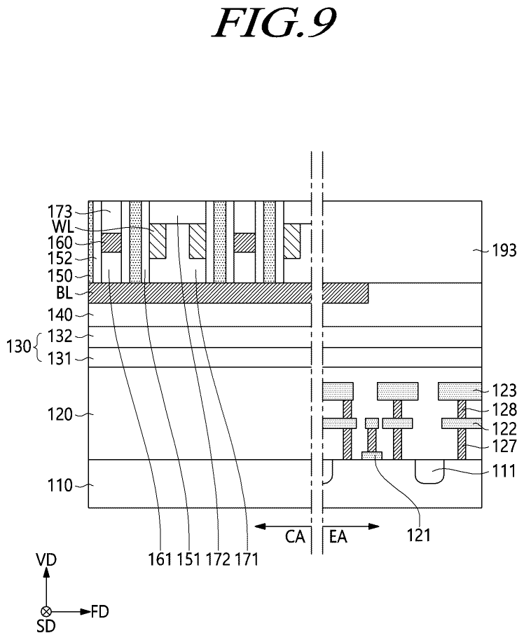

Referring to FIG. 8, a second semiconductor chip CW and a first semiconductor chip PW may be bonded together. The second semiconductor chip may be reversed and positioned over the first semiconductor chip with one side of the second bonding insulating layer 132 included in the second semiconductor chip CW may be bonded to one side of the first bonding insulating layer 131 included in the first semiconductor chip PW. The second semiconductor chip CW may be located on the first semiconductor chip PW.

Referring to FIG. 9, the first substrate 600 and the sixth insulating layer 610 may be removed. For example, the first substrate 600 may be removed through a grinding process or a chemical mechanical polishing (CMP) process and the sixth insulating layer 610 may be removed through a wet-etching process.

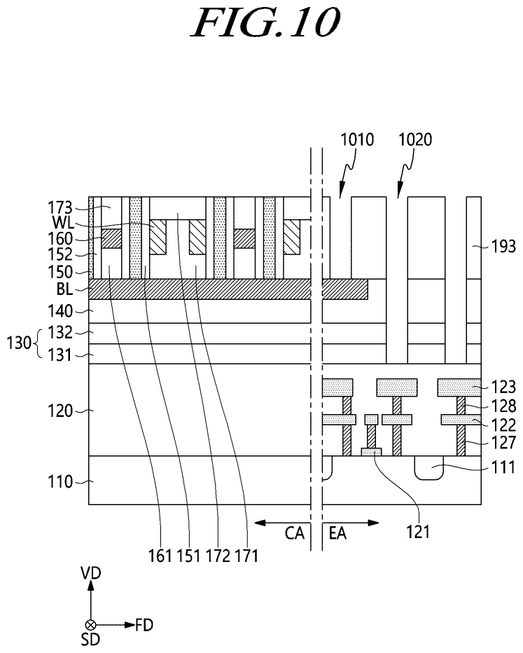

Referring to FIG. 1, FIG. 2, and FIG. 10, first and second through holes 1010 and 1020 may be formed in the extension area EA. The process of forming the first through hole 1010 may include a process of removing the third insulating layer 193. As the first through hole 1010 is formed, the upper surface of the bit line BL may be exposed.

The process of forming the second through hole 1020 may include a process of removing the third insulating layer 193, the second insulating layer 140, the second bonding insulating layer 132, and the first bonding insulating layer 131. As the second through hole 1020 is formed, the upper surface of the first insulating layer 120 may be exposed.

In an embodiment, the process of forming the first and second through holes 1010 and 1020 may include an anisotropic etching process. The vertical depth of the second through hole 1020 may be greater than the vertical depth of the first through hole 1010.

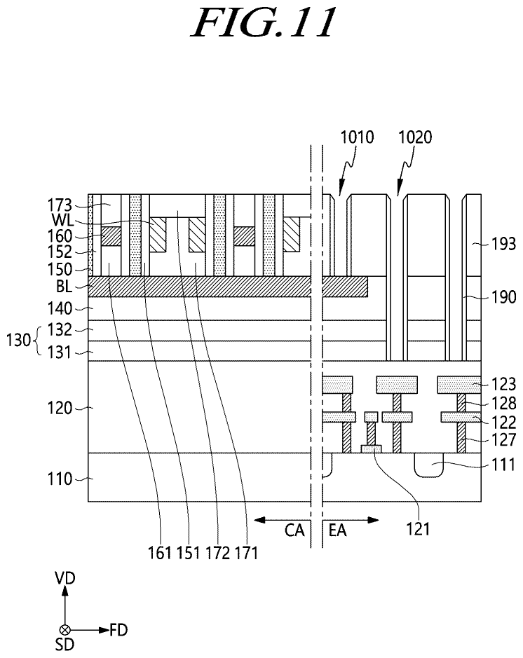

Referring to FIG. 11, spacer 190 may be formed along the side surfaces of the first and second through holes 1010 and 1020. In an embodiment, a thickness of the spacer 190 formed on the side surface of the first through hole 1010 and a thickness of the spacer 190 formed on the side surface of the second through hole 1020 may be the same. The lower surface of the spacer 190 formed on the side surface of the first through hole 1010 may contact the upper surface of the bit line BL. The lower surface of the spacer 190 formed on the side surface of the second through hole 1020 may contact the upper surface of the first insulating layer 120. The outer surface of the spacer 190 may contact the first bonding insulating layer 131 and the second bonding insulating layer 132.

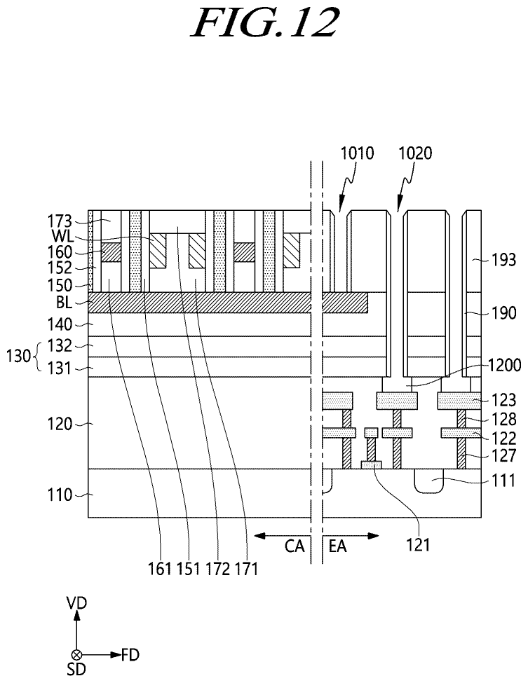

Referring to FIG. 12, a first insulating layer 120 located under the second through hole 1020 may be removed to form a recessed area 1200. The first insulating layer 120 may be removed in the vertical direction and in a direction parallel to a plane defined by a first direction FD and a second direction SD. In an embodiment, the process of removing the first insulating layer 120 may include an isotropic etching process. In an embodiment, a width of the recessed area 1200 in the first direction FD may be greater than a width of the second through hole 1020 in the first direction FD.

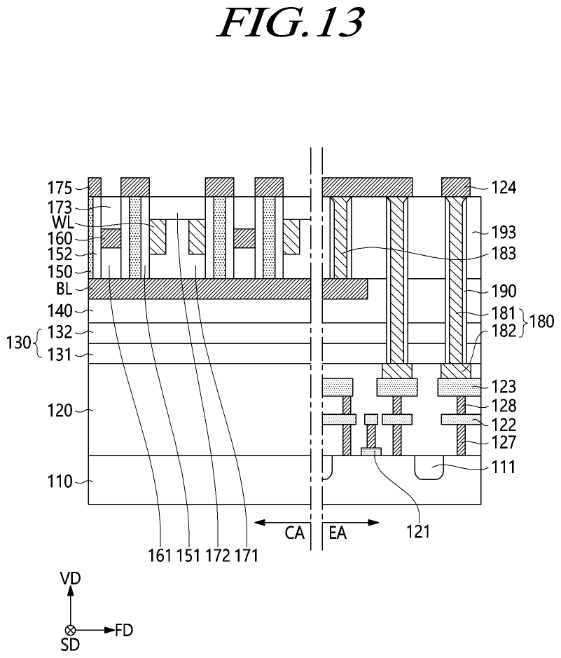

Referring to FIG. 12 and FIG. 13, there may be formed a bit line connection contact 183—filling the first through hole 1010, and a through contact 180 filling the second through hole 1020. The through contact 180 may fill the inside of the second through hole 1020 and the recessed area 1200 located below the second through hole 1020.

After the through contact 180 is formed, a contact plug 175 may be formed on the active layer 150 in the cell area CA, and a fourth wiring 124 may be formed on the bit line connection contact 183 and the through contact 180 in the extension area EA. The fourth wiring 124 may be formed in the same process operation as the process of forming the contact plug 175. For example, the fourth wiring 124 may include the same material as the material forming the contact plug 175.

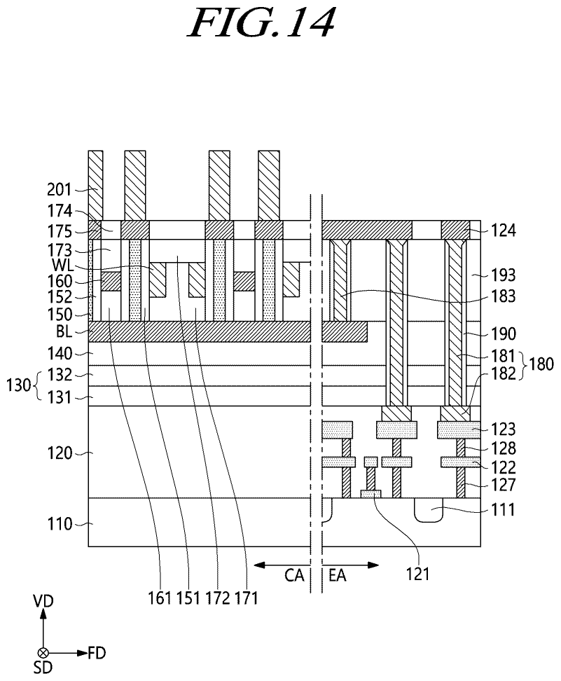

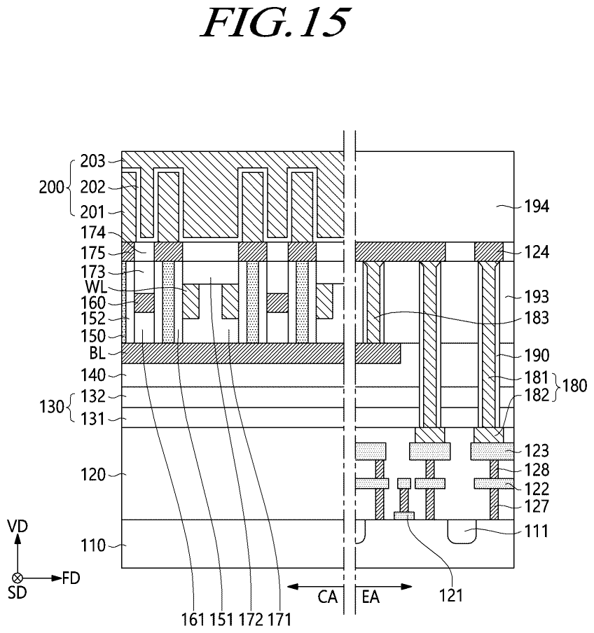

Referring to FIG. 14, there may be formed a fourth insulating pattern 174 covering the contact plug 175 and the fourth wiring 124. The fourth insulating pattern 174 may be located between the contact plugs 175 in the cell area CA and may be located between the fourth wiring 124 in the extension area EA.

After the fourth insulating pattern 174 is formed, a lower electrode 201 may be formed on the contact plug 175 in the cell area CA. The lower electrode 201 may be formed on the upper surface of a corresponding contact plug 175. The lower electrode 201 may not be formed in the extension area EA.

Referring to FIG. 15, a dielectric layer 202 may be formed on the lower electrode 201 and the fourth insulating pattern 174 in the cell area CA. In an embodiment, the dielectric layer 202 may be conformally formed on the side surface of the lower electrode 201, the upper surface of the lower electrode 201 and the upper surface of the fourth insulating pattern 174. The dielectric layer 202 may cover the side surface and the upper surface of the lower electrode 201 and the upper surface of the fourth insulating pattern 174. An upper electrode 203 may be formed on the dielectric layer 202. The dielectric layer 202 and the upper electrode 203 may not be disposed in the extension area EA. A fourth insulating layer 194 may be formed in the extension area EA to cover the fourth wiring 124.

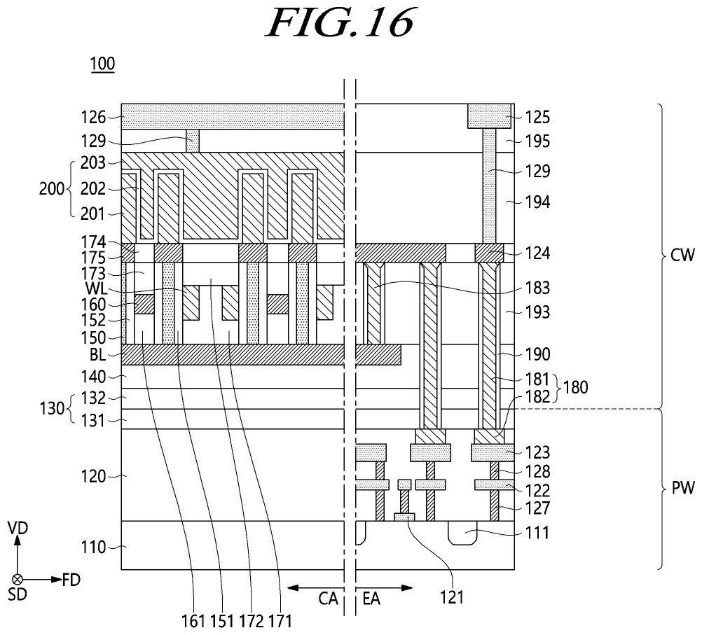

Referring to FIG. 16, a fifth insulating layer 195 may be formed on the upper electrode 203 and the fourth insulating layer 194. After the fifth insulating layer 195 is formed, a third contact 129 penetrating the fifth insulating layer 195 may be formed. In the cell area CA, the third contact 129 may contact the upper surface of the upper electrode 203. In the extension area EA, the third contact 129 may contact the upper surface of the fourth wiring 124.

A sixth wiring 126 may be formed on the third contact 129 in the cell area CA. A fifth wiring 125 may be formed on the third contact 129 in the extension area EA. The fifth wiring 125 and the sixth wiring 126 may each be formed within the fifth insulating layer 195.

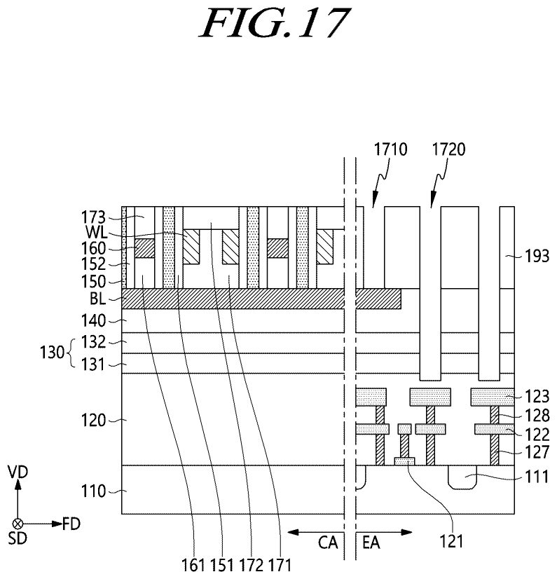

FIGS. 17 to 25 illustrate other methods for forming a memory device according to embodiments of the present disclosure.

The memory device illustrated in FIG. 17 may be formed by the same method as the method for forming a memory device described with reference to FIGS. 6 to 9.

Referring to FIG. 3 and FIG. 17, a first through hole 1710 and a second through hole 1720 may be formed in the extension area EA. The process of forming the first through hole 1710 may include a process of removing the third insulating layer 193. As the first through hole 1710 is formed, the upper surface of the bit line BL may be exposed.

The process of forming the second through hole 1720 may include a process of removing the third insulating layer 193, the second insulating layer 140, the second bonding insulating layer 132, the first bonding insulating layer 131, and the first insulating layer 120. The second through hole 1720 may extend into the interior of the first insulating layer 120 in the vertical direction. The lower surface of the second through hole 1720 may be positioned at a level lower in the vertical direction than the upper surface of the first insulating layer 120.

In an embodiment, the process of forming the first and second through holes 1710 and 1720 may include an anisotropic etching process. A vertical depth of the second through hole 1720 may be greater than a vertical depth of the first through hole 1710.

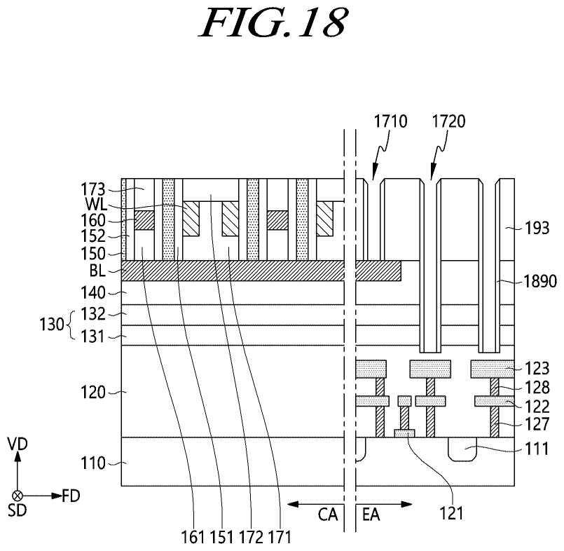

Referring to FIG. 18, a spacer 1890 may be formed along the side surfaces of the first and second through holes 1710 and 1720. In an embodiment, a thickness of the spacer 1890 formed on the side surface of the first through hole 1710 and the thickness of the spacer 1890 formed on the side surface of the second through hole 1720 may be the same. The lower surface of the spacer 1890 formed on the side surface of the first through hole 1710 may contact an upper surface of the bit line BL. The lower surface of the spacer 1890 formed on the side surface of the second through hole 1720 may contact the first insulating layer 120. The outer surface of the spacer 1890 may contact the first bonding insulating layer 131, the second bonding insulating layer 132, and the first insulating layer 120.

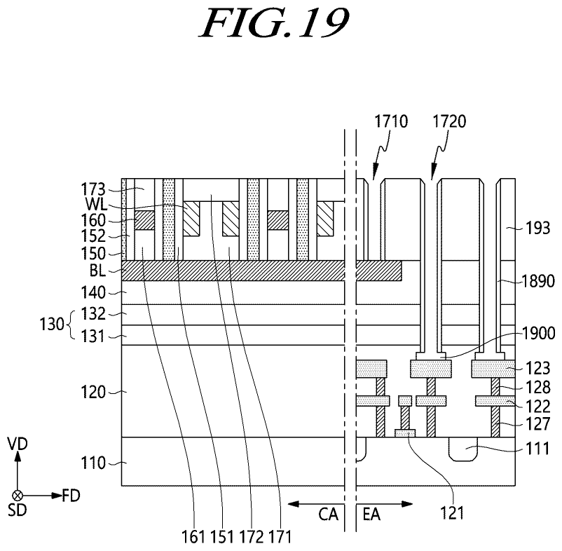

Referring to FIG. 19, the first insulating layer 120 located below the second through hole 1720 may be removed to form a recessed area 1900. The first insulating layer 120 may be removed in a vertical direction and in a direction parallel to a plane defined by a first direction FD and a second direction SD. In an embodiment, the process of removing the first insulating layer 120 may include an isotropic etching process. In an embodiment, a width of the recessed area 1900 in the first direction FD may be greater than a width of the second through hole 1720 in the first direction FD.

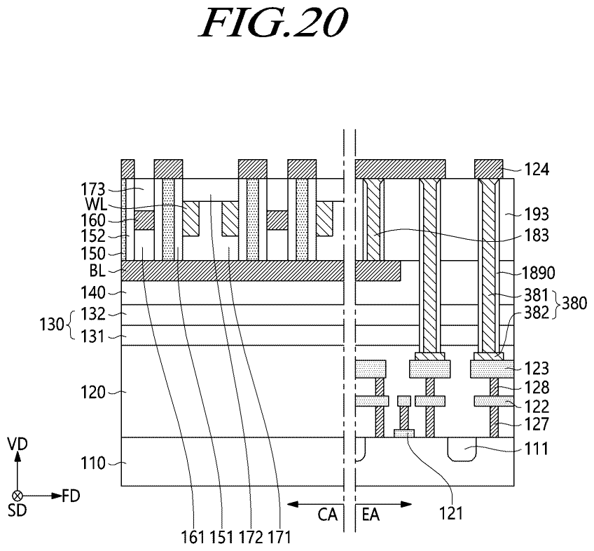

Referring to FIG. 19 and FIG. 20, the bit line connection contact 183 filling the first through hole 1710 may be formed, and the through contact 380 filling the second through hole 1720 may be formed. The through contact 380 may fill the inside of the second through hole 1720 and the recessed area 1900 located below the second through hole 1720.

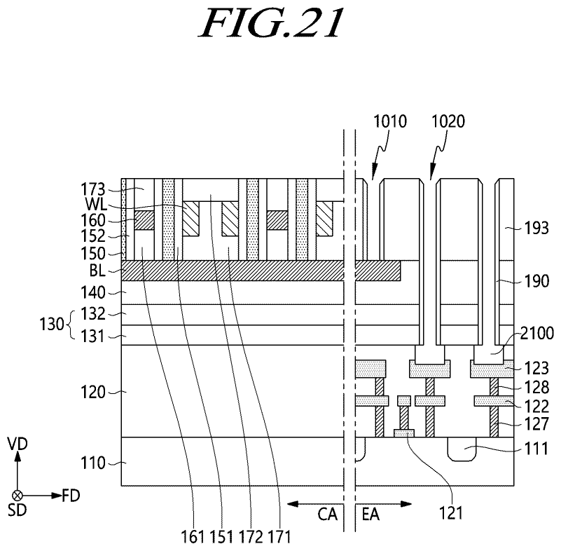

The memory device illustrated in FIG. 21 may be formed by the same method as the method of forming the memory device described with reference to FIGS. 6 to 11.

Referring to FIGS. 4 and 21, a part of the first insulating layer 120 and the third wiring 123 located below the second through hole 1020 may be removed to form a recessed area 2100. The recessed area 2100 may extend into the inside of the third wiring 123 in the vertical direction. The first insulating layer 120 and the third wiring 123 may be removed in the vertical direction and in a direction parallel to a plane defined by the first direction FD and the second direction SD. In an embodiment, the process of removing the first insulating layer 120 and the third wiring 123 may include an isotropic etching process.

In an embodiment, a width of the recessed area 2100 in the first direction FD may be greater than a width of the second through hole 1020 in the first direction FD. In an embodiment, the lower surface of the recessed area 2100 may be located at a lower level than the upper surface of the third wiring 123.

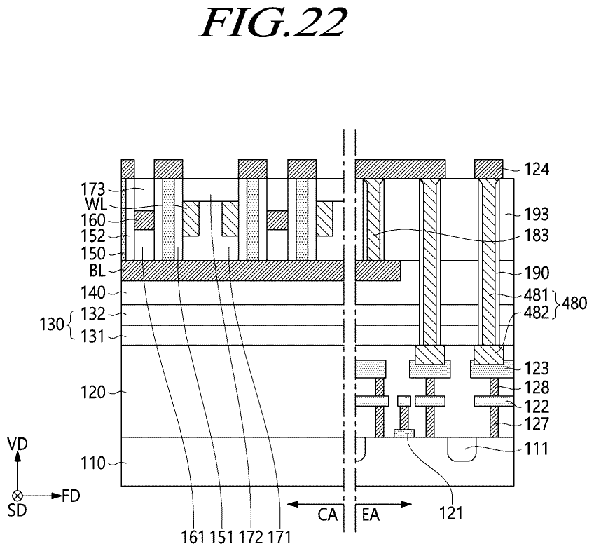

Referring to FIG. 21 and FIG. 22, the bit line connection contact 183 may be formed to fill the first through hole 1010, and a through contact 480 may be formed to fill the second through hole 1020. The through contact 480 may fill the inside of the second through hole 1020 and the recessed area 2100 located below the second through hole 1020.

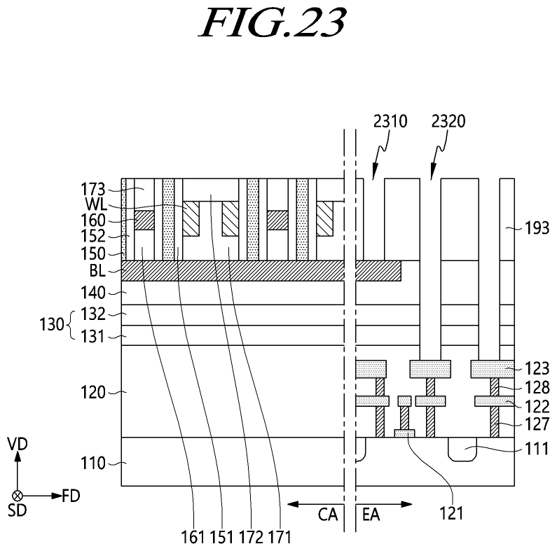

The memory device illustrated in FIG. 23 may be formed by the same method as the method of forming the memory device described with reference to FIGS. 6 to 9.

Referring to FIG. 5 and FIG. 23, a first through hole 2310 and a second through hole 2320 may be formed in the extension area EA. The process of forming the first through hole 2310 may include a process of removing the third insulating layer 193. As the first through hole 2310 is formed, the upper surface of the bit line BL may be exposed.

The process of forming the second through hole 2320 may include a process of removing the third insulating layer 193, the second insulating layer 140, the second bonding insulating layer 132, the first bonding insulating layer 131, and the first insulating layer 120. The second through hole 2320 may extend into the interior of the first insulating layer 120 in the vertical direction. As the second through hole 2320 is formed, the upper surface of the second wiring 123 may be exposed. The lower surface of the second through hole 2320 may be located at a lower level in the vertical direction than the upper surface of the first insulating layer 120. In an embodiment, the lower surface of the second through hole 2320 may be located at the same level as the upper surface of the third wiring 123.

In an embodiment, the process of forming the first and second through holes 2310 and 2320 may include an anisotropic etching process. A depth of the second through hole 2320 in the vertical direction may be greater than a depth of the first through hole 2310 in the vertical direction.

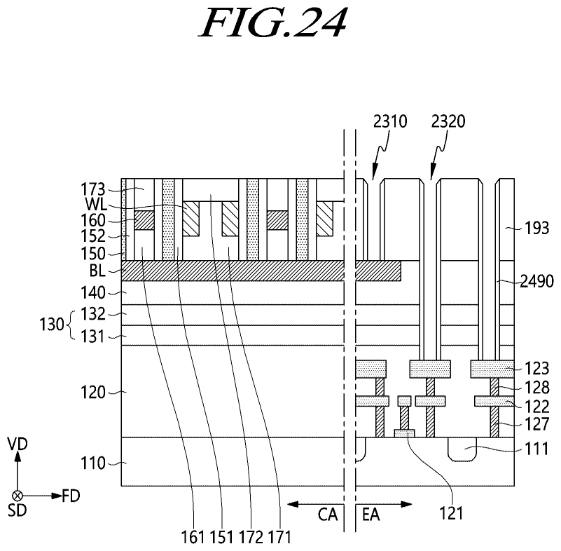

Referring to FIG. 24, a spacer 2490 may be formed along the side surfaces of the first through hole 2310 and the second through hole 2320. In an embodiment, the thickness of the spacer 2490 formed on the side surface of the first through hole 2310 may be the same as the thickness of the spacer 2490 formed on the side surface of the second through hole 2320. The lower surface of the spacer 2490 formed on the side surface of the first through hole 2310 may contact the upper surface of the bit line BL in the extension area EA. The lower surface of the spacer 2490 formed on the side surface of the second through hole 2320 may contact the upper surface of the third wiring 123 in the extension area EA. The outer surface of the spacer 2490 may contact the first bonding insulating layer 131, the second bonding insulating layer 132, and the first insulating layer 120.

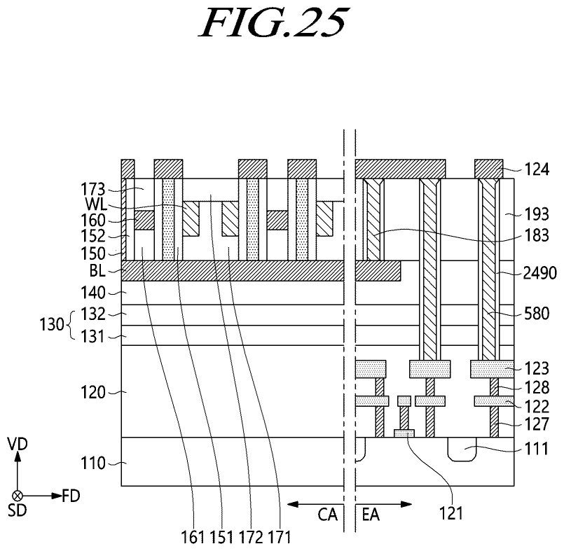

Referring to FIG. 24 and FIG. 25, a bit line connection contact 183 may be formed to fill the first through hole 2310, and a through contact 580 may be formed to fill the second through hole 2320. The through contact 580 may fill the inside of the second through hole 2320.

Referring to FIG. 1 and FIG. 2 again, the through contact 180 may penetrate the first bonding insulating layer 131 and the second bonding insulating layer 132 in the vertical direction. A spacer may be disposed between the side surface of the through contact 180 and the first bonding insulating layer 131 and the second bonding insulating layer 132. The through contact 180 may include a first portion 181 penetrating the first bonding insulating layer 131 and the second bonding insulating layer 132 and a second portion 182 located below the first portion 181. The width of the second portion 182 in the first direction FD may be greater than the width of the first portion 181 in the first direction FD.

According to the embodiments of the present disclosure, since a spacer 190 is disposed between the side surface of the through contact 180 and the bonding insulating layer 130, there may be prevented a short between the through contacts 180 due to a bridge formed between adjacent through contacts 180. Specifically, a void may be generated at the bonding interface during the process of bonding the second semiconductor chip CW and the first semiconductor chip PW. In particular, a void may be generated at the bonding interface between adjacent through contacts 180. If a void occurs at the bonding interface, when bonding the second semiconductor chip CW and the first semiconductor chip PW and forming the through contact 180, a conductive material may be deposited inside the void, which may cause a short between adjacent through contacts 180. However, according to the embodiments of the present disclosure, since a spacer 190 is disposed on the side of the through contact 180, it is possible to prevent a short between adjacent through contacts 180 even if a void occurs. Therefore, the memory device according to the embodiments of the present disclosure may prevent deterioration of device characteristics due to process defects.

In addition, according to the embodiments of the present disclosure, the width of the second portion 182 of the through contact 180 in the first direction FD may be greater than the width of the first portion 181 in the first direction FD. Since a contact area between the through contact 180 and the third wiring 123 is large, the contact resistance may be reduced between the through contact 180 and the third wiring 123. That is, even when the spacer 190 is disposed on the side of the through contact 180 and the width of the through contact 180 is reduced, the width of the through contact 180 may be increased at a part where the through contact 180 and the third wiring 123 contact, thereby ensuring low contact resistance.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, since the embodiments disclosed in this disclosure are not intended to limit the technical idea of this disclosure but to describe the technical idea of this disclosure, the scope of the technical idea of this disclosure is not limited by these embodiments. The protection scope of this disclosure should be interpreted by the claims below, and all technical ideas within the equivalent scope should be interpreted as being included in the scope of the rights of this disclosure. Furthermore, the embodiments may be combined to form additional embodiments.

What is claimed is:

1. A memory device comprising:
a first semiconductor chip including a first bonding insulating layer;
a second semiconductor chip bonded to the first semiconductor chip and including a second bonding insulating layer;
a through contact including a first portion vertically penetrating the first bonding insulating layer and the second bonding insulating layer, and a second portion located below the first portion and having a width greater than a width of the first portion; and
a spacer disposed on a side surface of the first portion of the through contact.

2. The memory device of claim 1, wherein an upper surface of the second portion of the through contact contacts a lower surface of the spacer.

3. The memory device of claim 1, wherein the spacer is located between the first portion of the through contact and the first bonding insulating layer and the second bonding insulating layer.

4. The memory device of claim 1, wherein a lower surface of the spacer forms substantially the same plane as a lower surface of the first bonding insulating layer.

5. The memory device of claim 1, wherein the spacer protrudes downward from a lower surface of the first bonding insulating layer.

6. The memory device of claim 5, wherein an upper surface of the second portion of the through contact is spaced apart from the first bonding insulating layer.

7. The memory device of claim 1, wherein the first semiconductor chip further includes a wiring located below the second portion of the through contact and connected to the second portion of the through contact, and
wherein the second portion of the through contact extends into an interior of the wiring in a vertical direction.

8. The memory device of claim 1, wherein the second semiconductor chip further includes a cell area and an extension area around the cell area, and the through contact is located in the extension area.

9. The memory device of claim 1, wherein the second semiconductor chip further includes a bit line extending in a first direction parallel to a lower surface of the second semiconductor chip, and
wherein the through contact is located outside an area where the bit line is disposed in the first direction.

10. The memory device of claim 1, wherein an upper surface of the first bonding insulating layer is bonded to a lower surface of the second bonding insulating layer.

11. A memory device comprising:
a bonding insulating layer including a first bonding insulating layer, and a second bonding insulating layer disposed on the first bonding insulating layer and bonded to the first bonding insulating layer;
a through contact including a first portion vertically penetrating the bonding insulating layer, and a second portion located below the first portion and having a width greater than a width of the first portion; and
a spacer disposed between the first portion of the through contact and the bonding insulating layer.

12. The memory device of claim 11, wherein an upper surface of the second portion of the through contact contacts a lower surface of the spacer.

13. The memory device of claim 11, wherein the spacer surrounds a side surface of the first portion of the through contact.

14. The memory device of claim 11, wherein a lower surface of the spacer forms substantially the same plane as a lower surface of the first bonding insulating layer.

15. The memory device of claim 11, wherein the spacer protrudes downward from a lower surface of the first bonding insulating layer.

16. The memory device of claim 11, wherein an upper surface of the second portion of the through contact is spaced apart from the first bonding insulating layer.

17. The memory device of claim 11, further comprising a wiring disposed below the first bonding insulating layer and connected to the second portion of the through contact,
wherein the second portion of the through contact extends vertically into an interior of the wiring.

18. A method for manufacturing a memory device, the method comprising:
forming a bonding insulating layer comprising a first bonding insulating layer, and a second bonding insulating layer bonded on the first bonding insulating layer;
forming a through contact including first and second portions, the first portion vertically penetrating the bonding insulating layer, and the second portion disposed below the first portion, the second portion having a width greater than a width of the first portion; and
forming a spacer disposed between the first portion of the through contact and the bonding insulating layer.
